(19) United States
(12) Patent Application Publication
(10) Pub. No.: US 2023/0305384 A1
(43) Pub. Date: Sep. 28, 2023

(54) LOW INTENSITY PHOTOMASK AND SYSTEM, METHOD AND PROGRAM PRODUCT FOR MAKING LOW INTENSITY PHOTOMASK FOR USE IN FLAT PANEL DISPLAY LITHOGRAPHY

(71) Applicant: PHOTRONICS, INC., Brookfield, CT (US)

(72) Inventors: Christopher Progler, Plano, TX (US); Young Mog Ham, Meridian, ID (US)

(21) Appl. No.: 18/123,420

(22) Filed: Mar. 20, 2023

Related U.S. Application Data
(60) Provisional application No. 63/323,527, filed on Mar. 25, 2022.

(51) Int. Cl. G03F 1/68; G03F 7/00; G03F 1/36

(52) U.S. Cl. CPC G03F 1/68; G03F 7/7055; G03F 7/70491; G03F 1/36; G03F 7/70791

(57) ABSTRACT

A method of manufacturing a photomask including the steps of receiving initial photomask design data associated with one or more patterns to be formed on a photomask and optimizing the initial photomask design data to minimize printing exposure energy while maintaining an acceptable pattern quality and size. In embodiments, the step of optimizing includes setting minimization of printing exposure energy as a priority design rule, setting optimization of pattern quality and size as a secondary design rule, iterating size of mask design features to determine a range of size biases that satisfy both the priority and secondary design rules so as to provide an initial optimized mask design, and adjusting mask variables over the range of size biases to determine mask variables that further optimize the initial optimized mask design to obtain a final optimized mask design.

### RELATED APPLICATION

This application claims priority to and the benefit of U.S. Provisional Application No. 63/323,527, filed Mar. 25, 2022 and entitled LOW INTENSITY PHOTOMASK AND SYSTEM, METHOD AND PROGRAM PRODUCT FOR MAKING LOW INTENSITY PHOTOMASK FOR USE IN FLAT PANEL DISPLAY LITHOGRAPHY, the contents of which are incorporated herein by reference in their entirety.

### FIELD OF THE INVENTION

The present invention generally relates to manufacturing of photomasks, and more particularly to manufacturing of photomasks used in flat panel display (FPD) lithography.

### BACKGROUND

The lithography process in flat panel display (FPD) manufacturing determines the capability and output capacity of flat panel products. Reducing process time at the lithography step is a key factor to reduce product turnaround time (TAT) and therefore enhance total product capacity output, which means improving productivity in the panel manufacturing.

When optimizing a mask layout to improve general lithographic performance, it is often necessary to adjust feature size, shapes and optical properties (e.g., phase shifting, transmission levels) of the mask in order to enhance the printing of the mask on the substrate. The optical properties are often adjusted using the mask structure, such as, for example, addition or tuning of thin films on the mask. In optical proximity correction, the edges of the mask feature are adjusted to have the printed mask feature most closely match the desired design feature when the mask is printed on the substrate by the lithography scanner. The typical figures of merit to guide the mask feature adjustments are related to pattern fidelity, focal range of the image and exposure latitude.

Photomask technology has contributed to the capability and productivity of integrated circuit (IC) and flat panel display (FPD) manufacturing, including the implementation of masks which improve process capability, margins and yield. Such masks include, for example, advanced binary or multi-tone masks and phase shifting masks, to name a few. These masks are mainly composed of a transparent substrate and absorbing (e.g., CrOx, CrON) and phase shift films (e.g., MoSi, SiN) that are patterned to deliver and sustain the optical, physical and mechanical requirements of the mask. Therefore, in mask fabrication, the optimum mask process condition and its controllability to process those films impacts patterning quality and performance of the mask in the lithography process.

However, for the FPD panel process, the design and processes are very different from conventional IC products and require special dedicated solutions. For example, leading edge panel product designs have much larger dimension features patterned over much larger areas and the families of shapes of such features are often different compared to advanced IC designs. In this regard, the higher performing mask making process used in complex IC designs are not necessary in FPD panel designs. Accordingly, there is a need for a mask making process that is more suitable to FPD lithography processes.

### SUMMARY OF THE INVENTION

An object of the present invention is to provide a mask making process in which mask shapes and mask structure are optimized to achieve the lowest printing exposure energy while still maintaining an acceptable pattern quality and size. This is opposed to the conventional technique used in, for example, IC lithography, where mask shapes and structure are optimized to achieve the optimal pattern quality and size. By effectively changing the optimization merit function priority from pattern quality improvement to lowest exposure dose level, a substantial improvement in throughput for the lithography scanner can be achieved while still maintaining acceptable image quality in the flat panel display application.

In exemplary embodiments, a method of manufacturing a photomask comprises: (A) receiving initial photomask design data associated with one or more patterns to be formed on a photomask; (B) optimizing the initial photomask design data to minimize printing exposure energy while maintaining an acceptable pattern quality and size, the step of optimizing comprising: 1. setting minimization of printing exposure energy as a priority design rule; 2. setting optimization of pattern quality and size as a secondary design rule; 3. iterating size of mask design features to determine a range of size biases that satisfy both the priority and secondary design rules so as to provide an initial optimized mask design; and 4. adjusting mask variables over the range of size biases to determine mask variables that further optimize the initial optimized mask design to obtain a final optimized mask design; and (C) generating optimized photomask design data based on the final optimized mask design.

In exemplary embodiments, the range of size biases comprises negative size biases.

In exemplary embodiments, wherein the range of size biases comprises positive size biases.

In exemplary embodiments, the mask variables comprise pattern edge compensation variables.

In exemplary embodiments, the mask variables comprise mask structure variables.

In exemplary embodiments, the mask variables comprise scanner illumination shape variables.

In exemplary embodiments, the mask variables comprise pattern edge compensation variables, mask structure variables, scanner illumination shape variables, and combinations thereof.

In exemplary embodiments, the method further comprises the step of performing optical proximity correction to the optimized photomask design data.

In exemplary embodiments, the method further comprises the step of providing a mask blank.

In exemplary embodiments, the method further comprises the step of processing the mask blank using the optimized photomask design data to form a photomask for use in a lithography process.

In exemplary embodiments, the photomask is a large-size photomask for use in a lithography process to manufacture a flat panel display (FPD).

In exemplary embodiments, a method of making a flat panel display comprising irradiating light from an optical energy source through a large-size photomask made in accordance with the method of claim 11 and onto a glass plate substrate in a photolithographic process so that the at least one circuit pattern is transferred from the large-size photomask to the glass plate substrate.

In exemplary embodiments, the flat-panel display is a liquid crystal display, an active matrix liquid crystal display, an organic light emission diode, a light emitting diode, a plasma display panel, or an active matrix organic light emission diode.

These and other features and advantages of the present invention will be presented in more detail in the following detailed description and the accompanying figures which illustrate by way of example principles of the invention.

### DESCRIPTION OF THE DRAWINGS

Various exemplary embodiments of this invention will be described in detail, with reference to the following figures, wherein:

FIG. 1 shows an original mask pattern layout as compared to a modified mask pattern layout in accordance with an exemplary embodiment of the present invention;

FIG. 2 is a chart showing trends in dose versus CD for differently biased line and space features in accordance with exemplary embodiments of the present invention;

FIG. 3 is a chart showing trends in dose verses CD for isolated contact features in accordance with exemplary embodiments of the present invention;

FIGS. 4A, 4B and 4C a range of variables on the mask that may be considered in a dose minimization optimization process in accordance with an exemplary embodiment of the present invention;

FIG. 5 is a simplified block diagram of an embodiment of a flat panel display (FPD) manufacturing system and an FPD manufacturing flow associated therewith, in accordance with an exemplary embodiment of the present invention;

FIG. 6 illustrates a schematic diagram of an exemplary mask enhancer system;

FIG. 7 depicts an exemplary computer system pertaining to a mask enhancer system in accordance with various embodiments of the present invention;

FIG. 8 shows a process for mask design optimization in accordance with an exemplary embodiment of the present invention;

FIG. 9 is a chart of position on the x axis (nm) versus aerial image intensity (mJ/cm²), showing an intensity profile according to an exemplary embodiment of the present invention;

FIG. 10 is a chart showing optimum energy level versus pattern sizes in accordance with an exemplary embodiment of the present invention;

FIG. 11 shows a process flow in which the low intensity mask design optimizing process described above with reference to FIG. 8 is augmented with additional steps;

FIGS. 12A-12C show an example of preparing a low intensity mask for an FPD design pattern according to an exemplary embodiment of the present invention;

FIG. 13 shows PSM mask structure and intensity according to an exemplary embodiment of the present invention;

FIG. 14 shows comparisons between intensity profiles of various PSM masks according to exemplary embodiments of the present invention;

FIG. 15 is a table showing percentage gain in productivity for a 1.5 um line-space pattern with variation in low intensity mask biasing and dose in accordance with exemplary embodiments of the present invention; and

FIG. 16 is a table showing percentage gain in productivity for a 1.8 um contact hole pattern with variation in low intensity mask biasing and dose in accordance with exemplary embodiments of the present invention.

### DETAILED DESCRIPTION

Flat-panel displays (FPDs) are electronic viewing technologies used to display content (e.g., still images, moving images, text, or other visual material) in a range of entertainment, consumer electronic, personal computer, and mobile devices, and many types of medical, transportation and industrial equipment. The current FPD types include, for example, LCD (Liquid Chrystal Display), AM LCD (Active Matrix Liquid Chrystal Display), OLED (Organic Light Emission Diode), LED (Light Emitting Diode), PDP (Plasma Display Panel) and AMOLED (Active Matrix OLED).

During manufacture of an FPD, an FPD lithography system irradiates light onto a photomask on which the original thin-film-transistor (TFT) circuit patterns are drawn, and the light exposes the patterns onto a glass plate substrate through a lens. On a large glass plate, the exposure process is repeated several times in order to form the patterns onto the entire plate.

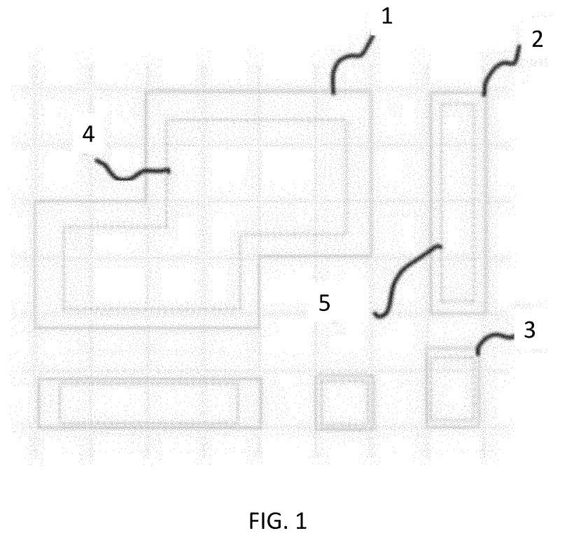

FIG. 1 shows an original mask pattern layout as compared to a modified mask pattern layout in accordance with an exemplary embodiment of the present invention. The original pattern layout, shown in solid line, is designed to obtain the target critical dimension (CD) or layout using an optimum dose condition to get +/−10% CD tolerance in the panel lithography. This conventional method comes from integrated circuit history which has a limitation due to the smaller process latitude in this type of lithography. However, in the flat panel lithography process, the larger pattern sizes often already have enough process window in exposure latitude and depth of focus so that there is more flexibility to adjust the pattern sizes for lowering the intensity threshold and therefore gain an increase in the throughput of the scanner. In this regard, the dotted line in FIG. 1 shows a preferred pattern bias to achieve the lower threshold exposure for the specific patterns in this example.

In this case, the lower intensity mask is generated by a smaller design shape, shown by the dotted lines in FIG. 1, giving a lower exposure time for these fully transmitting feature patterns. Although not shown in FIG. 1, certain other features on the mask, such as dark field contact hole designs, require a larger design feature bias (as opposed to smaller) to achieve a lower exposure time. In embodiments, these size biasing techniques are applied in the flat panel process to make a higher productivity mask.

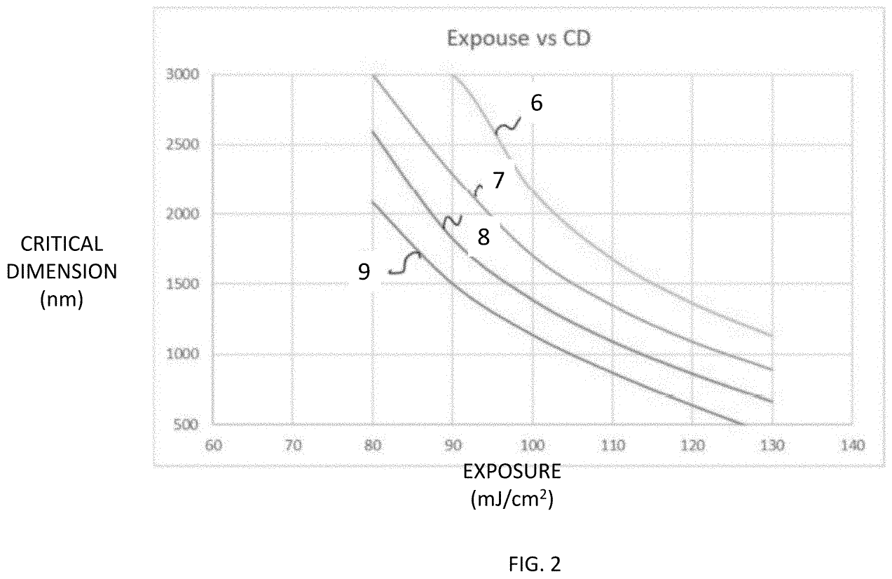

FIG. 2 is a chart showing trends in dose versus CD for differently biased line and space features. Line 6 is the data trend of exposure energy targeting a CD of 1.5 um for a line and space pattern. According to the chart, an exposure energy of 115 mJ/cm² must be used to obtain the 1.5 um CD target. However, in embodiments, the lithography process can be optimized to minimize exposure energy, in which case a smaller line with the same pitch size can be used. This is represented by lines 7, 8, and 9, where a lower exposure energy is required and a higher throughput is achieved to get the same pattern size on the panel.

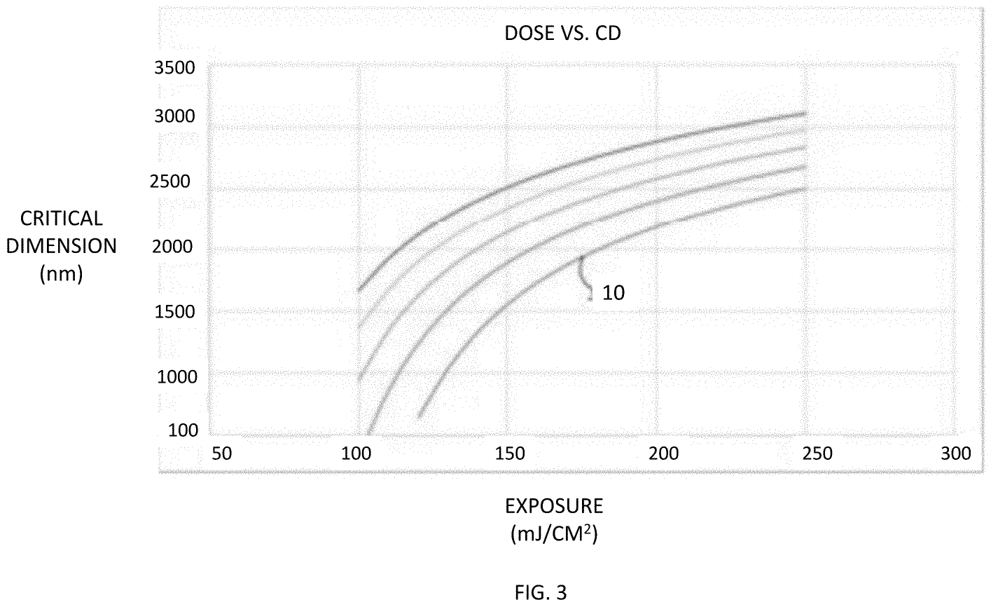

FIG. 3 is a chart showing the opposite effect when the design pattern is an isolated contact feature in accordance with exemplary embodiments of the present invention. Specifically, in this exemplary embodiment, a positive bias is applied to the design contacts to make a larger feature on the mask to achieve a lower dosage mask effect to define the target CD pattern on the panel. Line 10 shows the condition to obtain a 2.0 um contact CD with a 180 mJ/cm² dose while the other lines show the dose minimization effect when the contact features on the mask are made larger.

In embodiments, this bias optimization method can be applied for a full mask pattern made up of different feature shapes and sizes by simultaneously optimizing the bias of the shapes in accordance with the exposure minimization rule. More specifically, in embodiments, by using pattern correction tools with the exposure minimization bias rules, the printing dose for the entire mask can be effectively reduced while at the same time the pattern can print correctly on the panel for proper display device function.

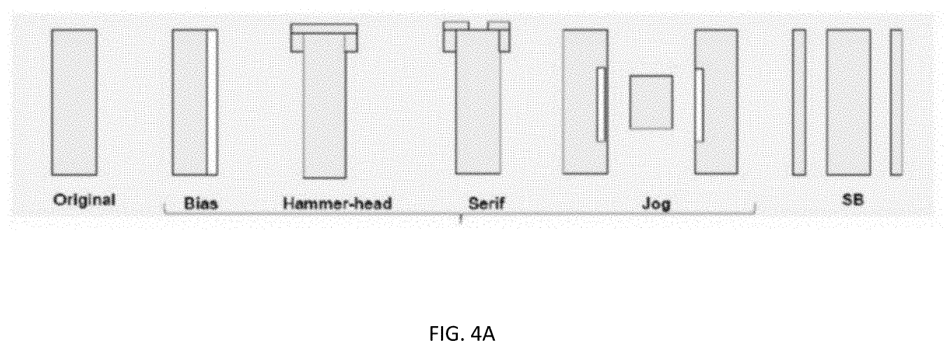

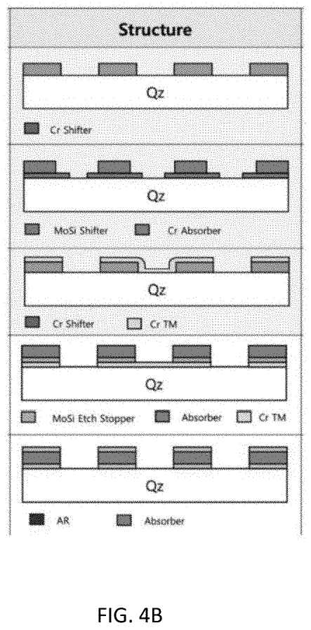

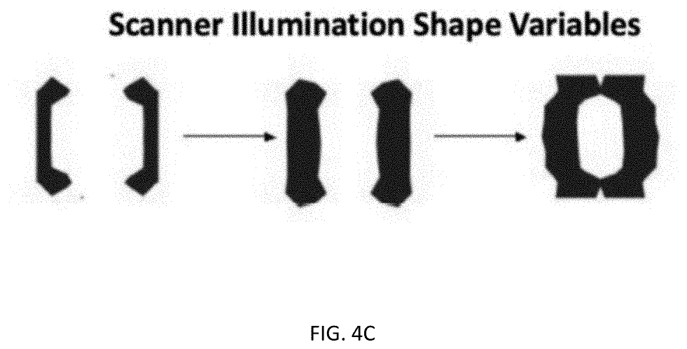

FIGS. 4A, 4B and 4C a range of variables on the mask that may be considered in a dose minimization optimization process in accordance with an exemplary embodiment of the present invention.

FIG. 4A show pattern edge compensation variables that may be adjusted to minimize dose according to an exemplary embodiment of the present invention. The pattern edge compensation variables may include, for example, bias, hammer-head, serif, jog, scattering bars, and combinations thereof, to name a few.

FIG. 4B show mask structure variables that may be adjusted to minimize dose according to an exemplary embodiment of the present invention. The mask structure variables may include, for example, phase shifter layers, absorber layers, transmissive layers, anti-reflective layers, and combinations thereof, to name a few.

FIG. 4C show scanner illumination shape variables that may be adjusted to minimize dose according to an exemplary embodiment of the present invention. The scanner illumination shape variables may include, for example, variations on arc-shaped illumination, such as, for example, adjustments in arc width, degree of arc, spacing of arcs, arc shape, and combinations thereof, to name a few.

In exemplary embodiments, the mask variables may be adjusted individually or in combination to minimize dose. For example, pattern edge compensation, mask structure and/or scanner illumination shape may be adjusted, either individually or in any combination of two or more of the variables.

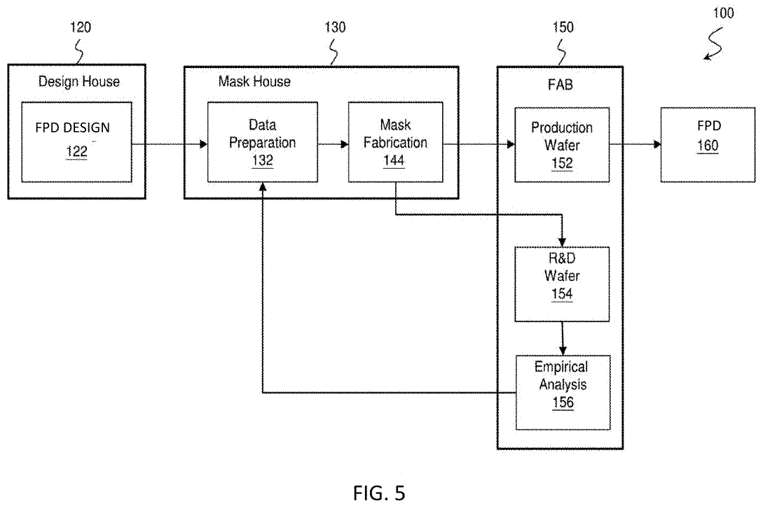

FIG. 5 is a simplified block diagram of an embodiment of a flat panel display (FPD) manufacturing system 100 and an FPD manufacturing flow associated therewith, in accordance with an exemplary embodiment of the present invention. The FPD manufacturing system 100 includes a plurality of entities, such as a design house 120, a mask house 130, and an FPD manufacturer 150 (i.e., a fab), that interact with one another in the design, development, and manufacturing cycles and/or services related to manufacturing an FPD device 160. The plurality of entities may be connected by a communications network, which may be a single network or a variety of different networks, such as an intranet and the Internet, and may include wired and/or wireless communication channels. Each entity may interact with other entities and may provide services to and/or receive services from the other entities. In embodiments, one or more of the design house 120, mask house 130, and FPD manufacturer 150 may have a common owner, and may even coexist in a common facility and use common resources.

In various embodiments, the design house 120, which may include one or more design teams, generates an FPD design layout 122. The FPD design layout 122 may include various geometrical patterns designed for the fabrication of the FPD device 160. By way of example, the geometrical patterns may correspond to patterns of metal, oxide, or semiconductor layers that make up the various components of the FPD device 160 to be fabricated. The various layers combine to form various features of the FPD device 160, such as, for example, thin film transistors (TFTs). For example, various portions of the FPD design layout 122 may include features such as an active region, a gate electrode, source and drain regions, metal lines or vias of a metal interconnect, openings for bond pads, as well as other features known in the art which are to be formed on an FPD glass substrate and various material layers disposed on the glass substrate. In exemplary embodiments, the design house 120 implements a design procedure to form the FPD design layout 122. The design procedure may include logic design, physical design, and/or place and route. The FPD design layout 122 may be presented in one or more data files having information related to the geometrical patterns which are to be used for fabrication of the FPD device 160. In embodiments, the FPD design layout 122 may be expressed in various formats, such as, for example, an Open Artwork System Interchange Standard (OASIS) file format, a GDSII file format, or DFII file format, to name a few.

In embodiments, the design house 120 may transmit the FPD design layout 122 to the mask house 130, for example, via the network connection described above. The mask house 130 may then use the FPD design layout 122 to manufacture one or more masks to be used for fabrication of the various layers of the FPD device 160 according to the FPD design layout 122. In various examples, the mask house 130 performs mask data preparation 132, where the FPD design layout 122 is translated into a form that can be physically written by a mask writer, and mask fabrication 144, where the design layout prepared by the mask data preparation 132 is modified to comply with a particular mask writer and/or mask manufacturer and is then fabricated. In the example of FIG. 2, the mask data preparation 132 and mask fabrication 144 are illustrated as separate elements; however, in some embodiments, the mask data preparation 132 and mask fabrication 144 may be collectively referred to as mask data preparation.

In embodiments, the mask data preparation 132 includes application of one or more resolution enhancement technologies (RETs) to compensate for potential lithography errors, such as those that can arise from diffraction, interference, or other process effects. In embodiments, optical proximity correction (OPC) may be used to adjust line widths depending on the density of surrounding geometries, add “dog-bone” end-caps to the end of lines to prevent line end shortening, correct for electron beam (e-beam) proximity effects, or for other purposes. For example, OPC techniques may add sub-resolution assist features (SRAFs), which for example may include adding scattering bars, serifs, and/or hammerheads to the FPD design layout 122 according to optical models or rules such that, after a lithography process, a final pattern on a glass substrate is improved with enhanced resolution and precision. The mask data preparation 132 may also include further RETs, such as off-axis illumination (OAI), phase-shifting masks (PSM), other suitable techniques, or combinations thereof.

In embodiments, the mask data preparation 132 may include a mask process correction (MPC) that is used to correct errors introduced during the mask making process. For example, the MPC may be used to correct mask making process effects such as fogging, development and etch loading and e-beam proximity effects. In embodiments, the MPC process modifies a post-OPC design layout to compensate for limitations which may be encountered during mask fabrication 144.

In embodiments, the mask data preparation 132 may include lithography process checking (LPC) that simulates processing that will be implemented by the FPD manufacturer 150 to fabricate the FPD device 160. The LPC may simulate this processing based on the FPD design layout 122 to create a simulated manufactured device, such as the FPD device 160. The processing parameters in LPC simulation may include parameters associated with various processes of the FPD manufacturing cycle, parameters associated with tools used for manufacturing the FPD, and/or other aspects of the manufacturing process. By way of example, LPC may take into account various factors, such as aerial image contrast, depth of focus (DOF), mask error enhancement factor (MEEF), other suitable factors, or combinations thereof.

In embodiments, after a simulated manufactured device has been created by LPC, if the simulated device layout is not close enough in shape to satisfy design rules, certain steps in the mask data preparation 132, such as OPC and MPC, may be repeated to refine the IC design layout 122 further.

It should be understood that the above description of the mask data preparation 132 has been simplified for the purposes of clarity, and data preparation may include additional features such as a logic operation (LOP) to modify the FPD design layout according to manufacturing rules. Additionally, the processes applied to the FPD design layout 122 during data preparation 132 may be executed in a variety of different orders.

After mask data preparation 132 and during mask fabrication 144, a mask or a group of masks may be fabricated based on the modified FPD design layout. In embodiments, an electron-beam (e-beam) or a mechanism of multiple e-beams is used to form a pattern on a mask (photomask or reticle) based on the modified FPD design layout. In embodiments, a mask pattern includes opaque regions and transparent regions. A radiation beam, such as an ultraviolet (UV) beam, used to expose a radiation-sensitive material layer (e.g., photoresist) coated on a wafer, is blocked by the opaque region and transmitted through the transparent regions. In embodiments, a binary mask includes a transparent substrate (e.g., fused quartz) and an opaque material (e.g., chromium) coated in the opaque regions of the mask. In embodiments, the mask is formed using a phase shift technology. In a phase shift mask (PSM), various features in the pattern formed on the mask are configured to have a pre-configured phase difference to enhance image resolution and imaging quality. In embodiments, the phase shift mask can be an attenuated PSM or alternating PSM.

In embodiments, the FPD manufacturer 150 may use the mask (or masks) fabricated by the mask house 130 to transfer one or more mask patterns onto a production glass substrate 152 and thus fabricate the FPD device 160 on the production glass substrate 152. The FPD manufacturer 150 may include an FPD fabrication facility that may include a myriad of manufacturing facilities for the fabrication of a variety of different FPD products. For example, the FPD manufacturer 150 may include a first manufacturing facility for front end fabrication of a plurality of FPD products (i.e., front-end-of-line (FEOL) fabrication), while a second manufacturing facility may provide back end fabrication for the interconnection and packaging of the FPD products (i.e., back-end-of-line (BEOL) fabrication), and a third manufacturing facility may provide other services. In various embodiments, the production FPD 152 within and/or upon which the FPD device 160 is fabricated may include a glass substrate, where the glass type may be, for example, aluminosilicate glass, borosilicate glass, or fused silica, to name a few. In embodiments, a large-size photomask may be appropriately sized to accommodate photolithography processing of glass plate substrates used to form FPDs.

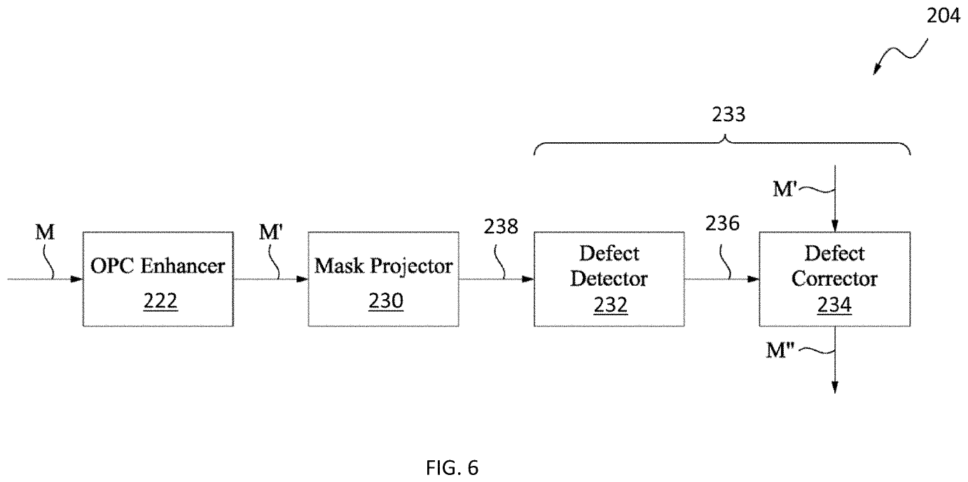

In exemplary embodiments, mask data preparation may involve the use of a mask enhancer system. In this regard, FIG. 6 illustrates a schematic diagram of an exemplary mask enhancer system 204 for enhancing photo mask layouts in accordance with some embodiments. Some embodiments of mask enhancer system 204 include an OPC enhancer 222 that receives the mask layout M that is produced by the design house 120 and produces the OPCed (e.g., the corrected) mask layout M. As described, OPC is a lithography technique that is used to correct or enhance the mask layout M, and produce improved imaging effects to reproduce, on the glass substrate, the original layout drawn by the FPD design house 120. For example, OPC can be used to compensate for imaging distortions due to optical diffraction. In some embodiments, the mask layout M is a data file having the information of the geometrical patterns to be produced on the substrate, and the OPC enhancer 222 modifies the data file and produces a corrected data file representing a corrected mask layout M′.

In exemplary embodiments, a mask projector 230 may be applied on the corrected mask layout M to produce a projected mask layout 238 on the wafer. In some embodiments, corrected mask layout M is a data file and the mask projector 230 simulates the projection of the corrected mask layout M′ on the wafer and produces the simulated projected mask layout 238. The defect detector 232 of the mask enhancer 204 inspects the projected mask layout 238 and finds the defective areas 236 of the projected mask layout 238. Although the corrected mask layout M′ is OPCed, defective areas may be produced when the corrected mask layout M′ is projected on the substrate 208.

In embodiments, a defect corrector 234 of the mask enhancer 204 may receive the defective areas 236 and the corrected mask layout M′ and implement further correction, e.g., enhancement, on the corrected mask layout M′, thereby producing the enhanced mask layout M″. In embodiments, defect detector 232 may be combined into the defect corrector 234 creating a layout detection and correction system 233 that receives the projected mask layout 238 and the corrected mask layout M′ and provides the enhanced mask layout M″.

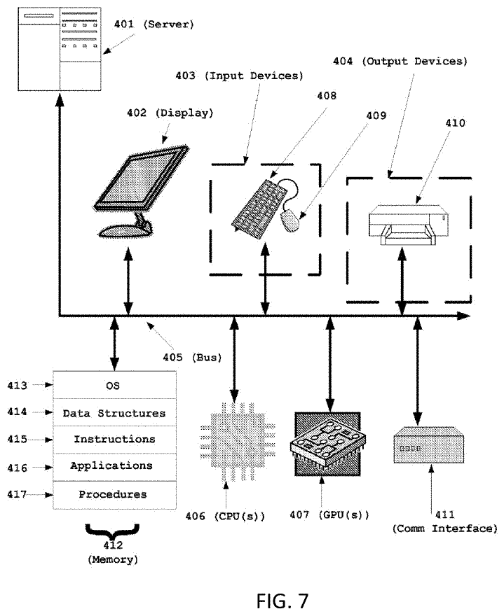

In exemplary embodiments, the mask enhancer system 204 may include specialized hardware components, software components, and/or combinations of both hardware and software components to carry out the various procedures related to enhancement and correction of a photomask as part of an FPD manufacturing process. In this regard, FIG. 7 depicts an exemplary computer system pertaining to a mask enhancer system in accordance with various embodiments of the present invention. In some embodiments, the computer system includes a server 401, display 402, one or more input interfaces 403, and one or more output interfaces 404, all conventionally coupled by one or more buses 405. Examples of suitable buses include, for example, PCI-Express®, AGP, PCI, ISA, and the like, to name a few.

The computer system may include any number of graphics processors. The graphics processor may reside on a motherboard such as being integrated with a motherboard chipset. One or more graphics processors may reside on external boards connected to the system through a bus such as an ISA bus, PCI bus, AGP port, PCI Express, or other system buses, to name a few. Graphics processors may on separate boards, each connected to a bus such as the PCI Express bus to each other and to the rest of the system. Further, there may be a separate bus or connection (e.g., Nvidia SLI or ATI CrossFire connection, to name a two) by which the graphics processors may communicate with each other. This separate bus or connection may be used in addition to or in substitution for system bus.

The server 401 may include one or more CPUs 406, one or more GPUs 407, and one or more memory modules 412. Each CPU and GPU may be a single core or multiple core unit. Examples of suitable CPUs include Intel Pentium®, Intel Core™ 2 Duo, AMD Athlon 64, AMD Opteron®, and the like, to name a few. Examples of suitable GPUs include Nvidia GeForce®, ATI Radeon®, and the like, to name a few. The input interfaces 403 may include a keyboard 408 and a mouse 409. The output interface 404 may include a printer 410.

In embodiments, the communications interface 411 is a network interface that allows the computer system to communicate via a wireless or hardwired network. The communications interface 411, may be coupled to a transmission medium (not shown), such as a network transmission line, for example, twisted pair, coaxial cable, fiber optic cable, and the like, to name a few. In another embodiment, the communications interface 411, provides a wireless interface, that is, the communication interface 411 uses a wireless transmission medium. Examples of other devices that may be used to access the computer system via communications interface 411 include cell phones, PDAs, personal computers, and the like (not shown), to name a few.

The memory modules 412 may generally include different modalities, illustratively semiconductor memory, such as random access memory (RAM), and disk drives as well as others. In various embodiments, the memory modules 412 store an operating system 413, data structures 414, instructions 415, applications 416, and procedures 417.

Storage devices may include mass disk drives, floppy disks, magnetic disks, optical disks, magneto-optical disks, fixed disks, hard disks, CD-ROMs, recordable CDs, DVDs, recordable DVDs (e.g., DVD-R, DVD+R, DVD-RW, DVD+RW, HD-DVD, or Blu-ray Disc), flash and other nonvolatile solid-state storage (e.g., USB flash drive), battery-backed-up volatile memory, tape storage, reader, and other similar media, and combinations of these.

In various embodiments, the specific software instructions, data structures, and data that implement various embodiments of the present invention are typically incorporated in the server 401. Generally, an embodiment of the present invention is tangibly embodied using a computer readable medium, for example, the memory, and includes of instructions, applications, and procedures which, when executed by the processor, causes the computer system to utilize the present invention, for example, the collection and analysis of data, pixelating structures, determining edge placement errors, moving edge fragments, optimizing edge fragment placements, and the like. The memory may store the software instructions, data structures, and data for any of the operating system, the data collection application, the data aggregation application, the data analysis procedures, and the like in semiconductor memory, in disk memory, or a combination of these.

A computer-implemented or computer-executable version of the invention may be embodied using, stored on, or associated with computer-readable medium. A computer-readable medium may include any medium that participates in providing instructions to one or more processors for execution. Such a medium may take many forms including, but not limited to, nonvolatile, volatile, and transmission media. Nonvolatile media includes, for example, flash memory, or optical or magnetic disks. Volatile media includes static or dynamic memory, such as cache memory or RAM. Transmission media includes coaxial cables, copper wire, fiber optic lines, and wires arranged in a bus. Transmission media can also take the form of electromagnetic, radio frequency, acoustic, or light waves, such as those generated during radio wave and infrared data communications.

For example, a binary, machine-executable version, of the software of the present invention may be stored or reside in RAM or cache memory, or on a mass storage device. The source code of the software of the present invention may also be stored or reside on mass storage device (e.g., hard disk, magnetic disk, tape, or CD-ROM). As a further example, code of the invention may be transmitted via wires, radio waves, or through a network such as the Internet.

The operating system may be implemented by any conventional operating system comprising Windows® (registered trademark of Microsoft Corporation), Unix® (registered trademark of the Open Group in the United States and other countries), Mac OS® (registered trademark of Apple Computer, Inc.), Linux® (registered trademark of Linus Torvalds), as well as others not explicitly listed here.

In various embodiments, the present invention may be implemented as a method, system, or article of manufacture using standard programming or engineering techniques, or both, to produce software, firmware, hardware, or any combination thereof. The term “article of manufacture” (or alternatively, “computer program product”) as used in this application is intended to encompass a computer program accessible from any computer readable device, carrier or media. In addition, the software in which various embodiments are implemented may be accessible through the transmission medium, for example, from a server over the network. The article of manufacture in which the code is implemented also encompasses transmission media, such as the network transmission line and wireless transmission media. Thus, the article of manufacture also includes the medium in which the code is embedded. Those skilled in the art will recognize that many modifications may be made to this configuration without departing from the scope of the present invention.

The computer system illustrated in FIG. 7 is not intended to limit the present invention. Other alternative hardware and/or software environments may be used without departing from the scope of the present invention.

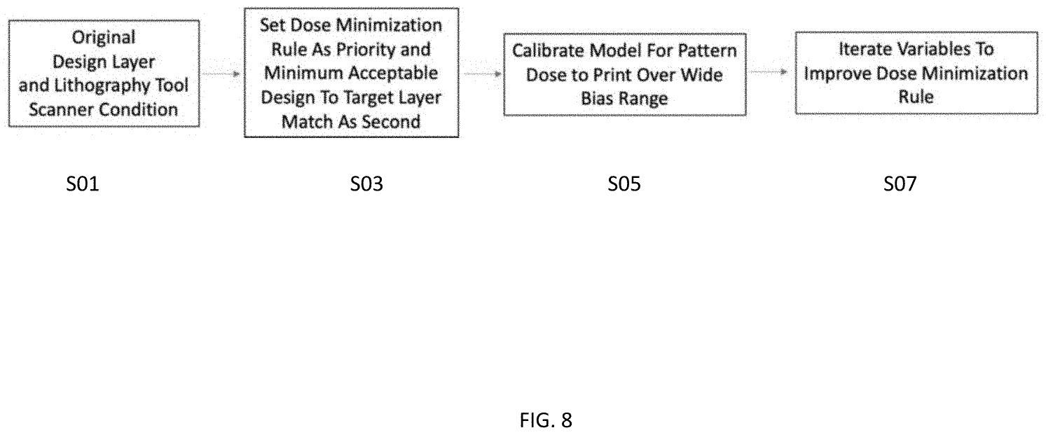

FIG. 8 shows a process for mask design optimization in accordance with an exemplary embodiment of the present invention. In step S01 of the process, a mask correction tool may receive or otherwise obtain data associated with an original mask design layer and lithography tool scanner illumination conditions. In step S03, a dose minimization rule is set as the priority rule, and minimum acceptable design to target layer match is set as a secondary rule. In embodiments, the minimum acceptable design may be a minimum acceptable CD tolerance range. In step S05, the mask model is calibrated for the pattern dose to print over wide bias range. In this step, mask data is generated representing variations in mask features in accordance with a bias range. For example, line and space patterns may be reduced in size relative to the original mask pattern data over a negative bias range, while contact hole patterns may be increased in size relative to the original mask pattern data over a positive bias range.

In step S07, pattern edge, mask structure and/or scanner illumination shape are varied over the negative and/or positive bias ranges to satisfy the minimum dose rule while still achieving minimum acceptable target layer match. In this step, only one of the variables may be adjusted over the bias ranges, or two or more of the variables in combination may be varied over the bias ranges, to determine which iteration achieves the minimum dose while maintaining minimum acceptable quality and size of features.

In embodiments, the process flow shown in FIG. 8 drives the mask pattern optimization to the low exposure case, which drives up throughput when the mask is applied in the lithography printing. Without being bound by theory, in panel manufacturing processes, the lithography process has a larger process margin compared to that of IC manufacturing. Large pattern designs and exposure tool capability allow for the use of low intensity masks in panel lithography processes for better throughput and productivity.

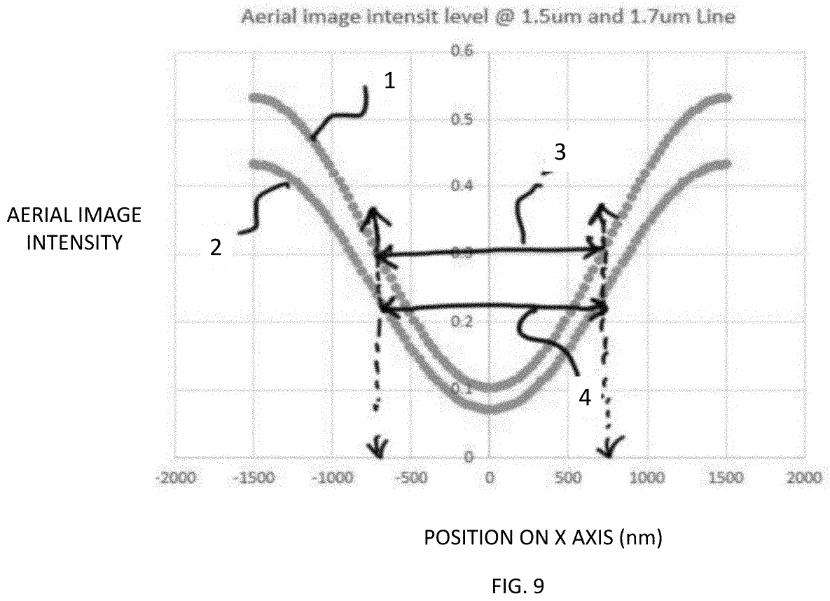

FIG. 9 is a chart of position on the x axis (nm) versus aerial image intensity (mJ/cm²), showing an intensity profile 1 of a 1.5 um line and 1.5 um space pattern (3.0 um pitch) and an intensity profile 2 is for a 1.7 um line and 1.3 um space pattern (3.0 um pitch) in accordance with exemplary embodiments of the present invention. In embodiments, such intensity profiles generated using results of aerial image simulation may be used to select optimum design and intensity level. In this example, for intensity profile 1, to get 1.5 um pattern size, intensity level or energy level will be close to 0.3 to achieve a target CD (shown as line 3). If 0.2 um oversizing is used (intensity profile 2) to produce a low intensity mask, target CD (shown as line 4) can be achieved using a 0.2 energy level. That is, a lower dose or energy can be used to define the same size pattern. Accordingly, a shorter exposure time can be used in panel lithography processes to increase panel process throughput and manufacturability.

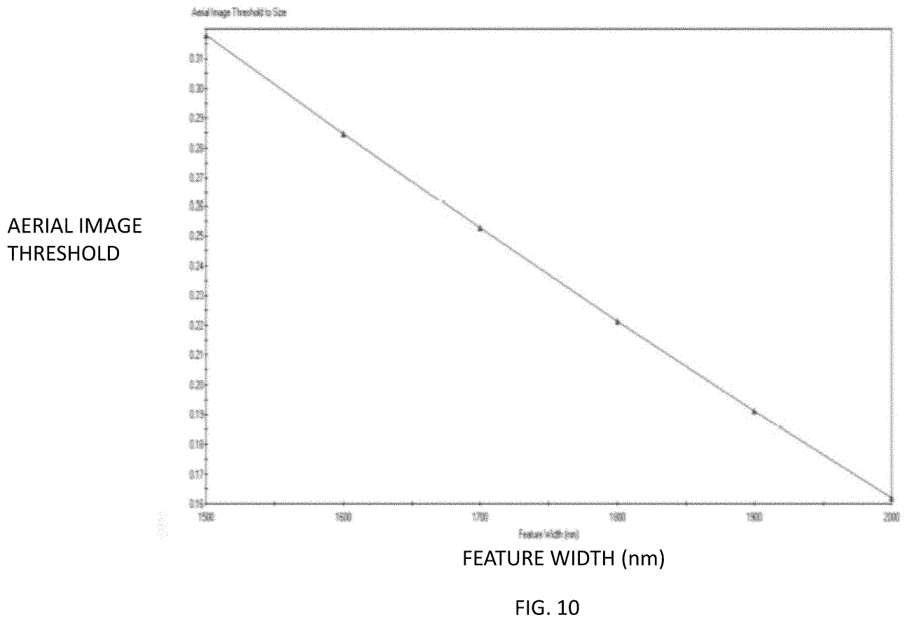

FIG. 10 is a chart showing optimum energy level versus pattern sizes in accordance with an exemplary embodiment of the present invention. With the use of a low intensity mask with optimum resizing, lower energy can be used as a trend of optimum dose condition.

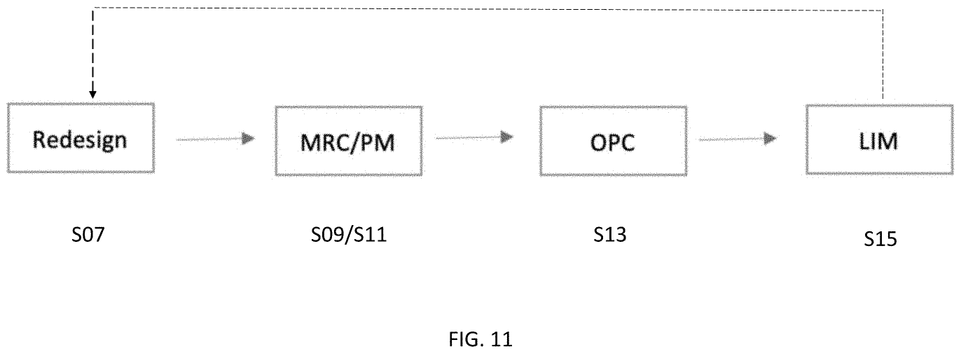

Since the current invention prioritizes the low exposure case instead of the pattern fidelity case as in conventional pattern correction methods, in embodiments features may be added to the optimization flow to identify and compensate for any issues that might arise from the prioritization of the dose minimization rule. In this regard, FIG. 11 shows a process flow in which the low intensity mask design optimizing process described above with reference to FIG. 8 is augmented with additional steps. The first additional (step S09) is MRC or Mask Rules Checking which ensures the low intensity mask design does not introduce mask shapes and features that are too complex to manufacture. The second additional step is PM or Pattern Matching (step S11) which selectively locates and adjusts special mask patterns to address printing issues that might have arisen due to the low intensity mask optimization process. The third additional step is OPC or Optical Proximity Correction (step S13) which continues to adjust the pattern for pattern quality while not overriding the dose minimization benefit of the low intensity mask design process flow. The final low intensity mask design as augments by these steps is then completed in step S15. In embodiments, as shown by the dashed arrow in FIG. 11, the overall low intensity mask design process may include any number of iterations of low intensity optimization with additional steps to compensate for any issues until a final mask design is achieved that meets desired parameters. In embodiments, the additional steps mentioned above may or may not be needed in the total low intensity mask data correction flow, and any number of these extra steps either individually or in combination may be included in the overall process.

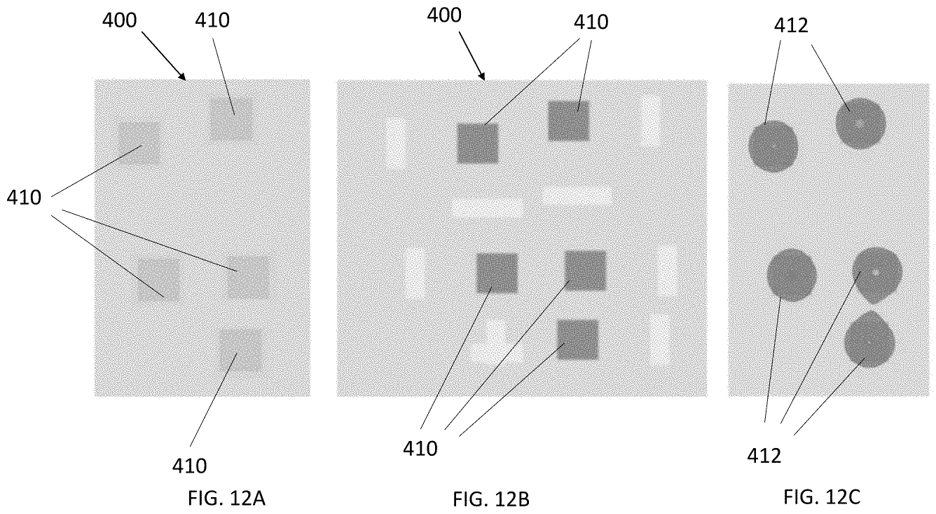

FIGS. 12A-12C show an example of preparing a low intensity mask for an FPD design pattern. The mask in this example is intended to form part of contact array layer in an FPD panel process. The original mask as redesigned as a low intensity mask design 400 is shown in FIG. 12A, including contact openings 410. An MRC tool may then be used to find any overlapping or rule violations in the design and process capability, and corrections may be made using applied rules in the MRC process and pattern matching. FIG. 12B shows the mask after the MRC and an OPC process, which can be applied to improve the process window or for other specific purposes. FIG. 12C shows a verification and validation step, where a simulation method for the optimized low intensity mask may be used to identify potential issues (such as the bridging issue shown in the simulated features 412 projected by the mask), which can then be corrected in the data for the final low intensity mask fabrication.

As described above with reference to FIGS. 4A-4C, in embodiments special illumination and mask structure conditions may be employed to the mask fabrication and printing to improve the effectiveness and dose reduction opportunity of a low intensity mask. In embodiments, the low intensity optimization may benefit from setting the phase shift and light transmission parameters (including multiple transmission levels) of the mask along with other film properties that can create a high contrast mask, thereby providing more latitude to optimize the low intensity mask design flow to achieve an even higher increase in productivity and speed for FPD production.

Masks used in FPD panel manufacturing processes are conventionally exposed using an exposure tool with a round-type aperture. In embodiments, a larger opened aperture type may be used to deliver a higher amount of energy onto the mask. Also, OAI (off-axis illumination) is now being used in the FPD realm (see FIG. 4C). In embodiments, OAI design and sizing may be optimized to improve the effectiveness of low intensity masks.

In addition, and again referring to FIG. 4B, mask technology in panel lithography may contribute to obtaining improved process windows and productivity in FPD manufacturing. In this regard, in embodiments, various types of masks may be used in the FPD manufacturing process, such as, for example, binary intensity masks (BIM), phase shift masks (PSM), RIM type PSM, high transmission mask (HTM), mixed PSM and HTM, and double sided anti-reflection mask (DAR), to name a few.

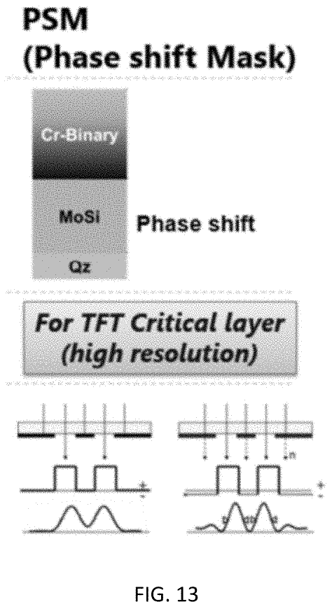

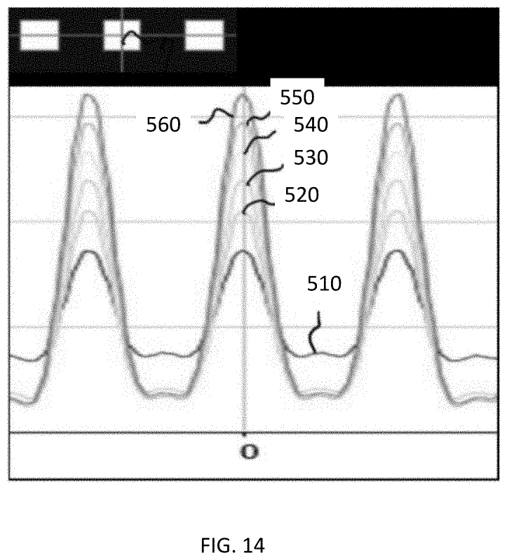

FIG. 13 shows PSM mask structure and intensity and FIG. 14 shows comparisons between intensity profiles of various PSM masks. In embodiments, PSM masks may be used in an FPD manufacturing process to improve process window and resolution. Without being bound by theory, a higher quality intensity profile may be obtained by 180 degree phase shifting through phase materials as shown in FIG. 13. In embodiments, a PSM mask may be treated to the low intensity mask optimization discussed herein to further enhance the overall process due to the improved intensity profile and higher contrast of such masks. As an example, FIG. 14 shows a simulation result for various mask types, illustrating that the intensity profile of PSMs has better contrast and profile property as compared to BIMs. Intensity profile 510 corresponds to a BIM mask, intensity profiles 520-560 corresponds to PSM masks ranging from 5% to 50% transmission, and intensity profile 570 corresponds to a contact mask.

In embodiments, feature bias can be applied to binary type masks with 1.5 um design rule using the dose minimization function to achieve a 10-30% improvement in FPD production. In embodiments, high contrast masks such as PSM masks achieve a 30% or more gain in productivity.

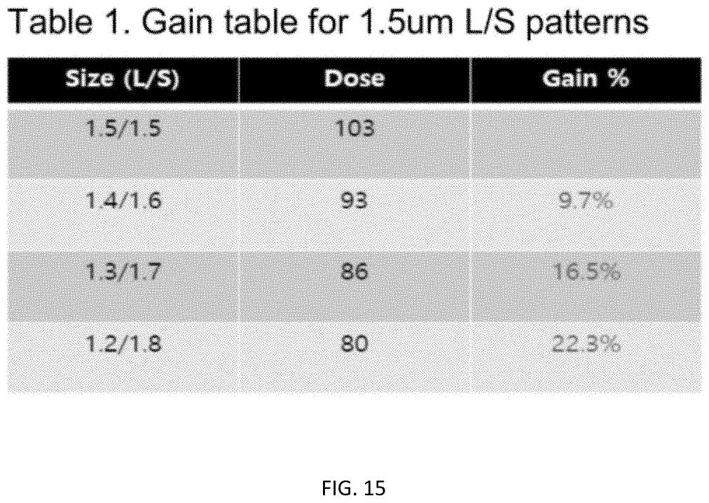

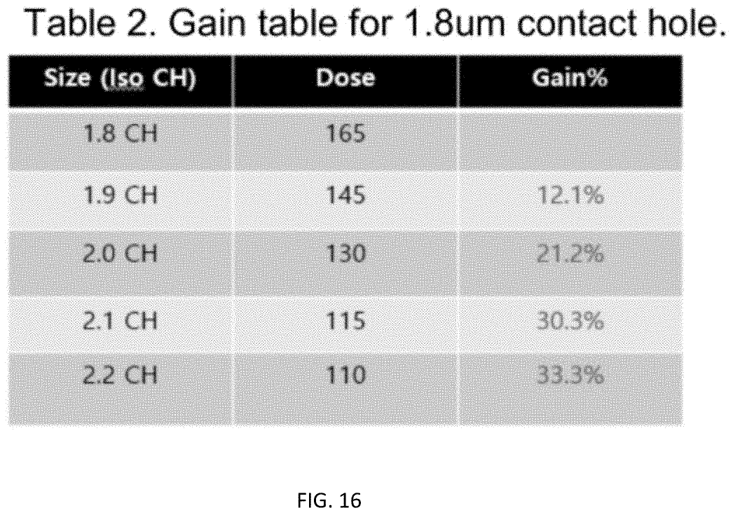

FIG. 15 is a table showing percentage gain in productivity for a 1.5 um line-space pattern with variation in low intensity mask biasing and dose in accordance with exemplary embodiment of the present invention, and FIG. 16 is a table showing percentage gain in productivity for a 1.8 um contact hole pattern with variation in low intensity mask biasing and dose in accordance with exemplary embodiments of the present invention. The tables in FIGS. 15 and 16 show that various redesign optimizations in accordance with exemplary embodiments results in significant improvements in process flow.

In embodiments, to counter issues with obtaining consistent results using the dose minimization processes described herein particularly when applied across FPD design layouts composed of patterns having various designs and design rules, rule checking may be verified using mask rule checker tools and critical patterns may be located using pattern matching tools. In embodiments, FPD OPC models may be applied to remove possible data errors in the full field FPD area.

While in the foregoing specification a detailed description of a specific embodiment of the invention was set forth, it will be understood that many of the details herein given may be varied considerably by those skilled in the art without departing from the spirit and scope of the invention.

1. A method of manufacturing a photomask, comprising:
(A) receiving initial photomask design data associated with one or more patterns to be formed on a photomask;
(B) optimizing the initial photomask design data to minimize printing exposure energy while maintaining an acceptable pattern quality and size, the step of optimizing comprising:
1. setting minimization of printing exposure energy as a priority design rule;
2. setting optimization of pattern quality and size as a secondary design rule;
3. iterating size of mask design features to determine a range of size biases that satisfy both the priority and secondary design rules so as to provide an initial optimized mask design; and
4. adjusting mask variables over the range of size biases to determine mask variables that further optimize the initial optimized mask design to obtain a final optimized mask design;
(C) generating optimized photomask design data based on the final optimized mask design.

2. The method of claim 1, wherein the range of size biases comprises negative size biases.

3. The method of claim 1, wherein the range of size biases comprises positive size biases.

4. The method of claim 1, wherein the mask variables comprise pattern edge compensation variables.

5. The method of claim 1, wherein the mask variables comprise mask structure variables.

6. The method of claim 1, wherein the mask variables comprise scanner illumination shape variables.

7. The method of claim 1, wherein the mask variables comprise pattern edge compensation variables, mask structure variables, scanner illumination shape variables, and combinations thereof.

8. The method of claim 1, further comprising the step of performing optical proximity correction to the optimized photomask design data.

9. The method of claim 1, further comprising the step of providing a mask blank.

10. The method of claim 9, further comprising the step of processing the mask blank using the optimized photomask design data to form a photomask for use in a lithography process.

11. The method of claim 10, wherein the photomask is a large-size photomask for use in a lithography process to manufacture a flat panel display (FPD).

12. A method of making a flat panel display comprising irradiating light from an optical energy source through a large-size photomask made in accordance with the method of claim 11 and onto a glass plate substrate in a photolithographic process so that the at least one circuit pattern is transferred from the large-size photomask to the glass plate substrate.

13. The method of claim 12, wherein the flat-panel display is a liquid crystal display, an active matrix liquid crystal display, an organic light emission diode, a light emitting diode, a plasma display panel, or an active matrix organic light emission diode.
